(19) United States
(12) Patent Application Publication
(10) Pub. No.: US 2023/0187107 A1
(43) Pub. Date: Jun. 15, 2023

(54) SHUNT RESISTOR

(71) Applicant: KOA CORPORATION, Nagano (JP)

(72) Inventors: Toshikazu KURIHARA, Nagano (JP); Tamotsu ENDO, Nagano (JP)

(21) Appl. No.: 17/924,308

(22) PCT Filed: May 6, 2021
(86) PCT No.: PCT/JP2021/017351

§ 371 Date: Nov. 9, 2022

(30) Foreign Application Priority Data
May 13, 2020 (JP) 2020-084745

(51) Int. Cl. H01C 7/13; H01C 17/00; H01C 1/148; H01C 1/144

(52) U.S. Cl. CPC H01C 7/13; H01C 17/006; H01C 1/148; H01C 1/144

(57) ABSTRACT

Provided is a shunt resistor with an enhanced strength and reduced electrical resistance between a resistive element and terminals of the shunt resistor. This shunt resistor includes a first terminal and a second terminal each made of an electrically conductive metal material; and a resistive element disposed between the first terminal and the second terminal. The first terminal and the second terminal each have a through-hole, and the resistive element is embedded in the through-holes of the first terminal and the second terminal in a depth direction thereof. Regions connecting the resistive element to the first terminal and the second terminal each have an alloy portion formed along an inner peripheral surface of the through-hole.

### CROSS-REFERENCE TO RELATED APPLICATIONS

The application is a 371 application of PCT/JP2021/017351 having an international filing date of May 6, 2021, which claims priority to JP 2020-084745 filed May 13, 2020, the entire content of each of which is incorporated herein by reference.

### TECHNICAL FIELD

The present invention relates to a shunt resistor.

### BACKGROUND ART

A shunt resistor is used for sensing current flowing through a semiconductor power module or the like mounted on an electric vehicle, for example.

Patent Literature 1 describes a shunt resistor which is easy to attach, does not require an excessively large attachment space, and is capable of performing highly accurate current sensing.

The shunt resistor described in Patent Literature 1 includes: a first terminal and a second terminal each made of an electrically conductive metal material and having a first plane, a second plane, and an outer peripheral surface around the planes; and resistive elements connected to the respective first planes and connecting the first terminal and the second terminal together, the respective first planes of the first terminal and the second terminal opposing each other. The joint area between the resistive elements and the first planes is smaller than the area of the first planes. The first terminal and the second terminal each have a hole portion penetrating through from the first plane to the second plane.

Such a shunt resistor may be referred to as a “bushing shunt (resistor).”

### CITATION LIST

### Patent Literature

Patent Literature 1: JP 2017-212297 A.

### SUMMARY OF INVENTION

### Technical Problem

In the shunt resistor disclosed in the above Patent Literature 1, a plurality of cylindrical resistive elements are arranged between the first terminal and the second terminal, and the opposite end faces of the resistive elements have a surface connection with the first terminal and the second terminal through welding, for example. Thus, there is a demand for enhancing the strength of the shunt resistor and reducing the electrical resistance.

An object of the present invention is to enhance the strength of a shunt resistor. In addition, an object of the present invention is to reduce the electrical resistance between the resistive elements and the terminals in the shunt resistor.

### Solution to Problem

According to an aspect of the present invention, there is provided a shunt resistor including: a first terminal and a second terminal each made of an electrically conductive metal material; and a resistive element disposed between the first terminal and the second terminal. The first terminal and the second terminal each have a through-hole. The resistive element is embedded in the through-holes of the first terminal and the second terminal in a depth direction thereof. Regions connecting the resistive element to the first terminal and the second terminal each have an alloy portion formed along an inner peripheral surface of the through-hole.

With the resistive element and the alloy portion formed by laser beam welding or electron beam welding, for example, the strength of the shunt resistor can be enhanced.

Preferably, the resistive element includes a plurality of resistive elements, and the plurality of resistive elements are provided in parallel and connect the first terminal and the second terminal together.

Preferably, the first terminal and the second terminal each have a flange portion formed at a position connected to the resistive element by reducing a diameter of the through-hole toward the position connected to the resistive element.

The flange portion allows securely fixing the first terminal and the second terminal.

At least a portion of the through-hole may be filled with solder, and the resistive element may be connected to a surface of the solder.

Since the resistive element is connected to the surface of the solder between the first terminal and the second terminal, the electrical resistance between the resistive element and the terminals in the shunt resistor can be reduced.

### Advantageous Effects of Invention

According to the present invention, the electrical resistance between the resistive elements and the terminals in the shunt resistor can be reduced. In addition, it is possible to suppress partial imbalance of the current density and the heat transfer effect of the shunt resistor and reduce manufacturing variations of a resistance value. The present invention also produces the effect of suppressing local heating at a large current.

Furthermore, the strength of the shunt resistor can be enhanced.

### BRIEF DESCRIPTION OF DRAWINGS

FIG. 1 is a perspective view illustrating an exemplary configuration of a shunt resistor according to an embodiment of the present invention.

FIG. 2 is a perspective view of the shunt resistor according to a first embodiment of the present invention, including the Ia-Ib cross section of the resistive elements of FIG. 1.

FIG. 3 is a cross-sectional view of the shunt resistor according to the first embodiment of the present invention, including the cross section of the resistive elements of FIG. 1 taken along line Ia-Ib.

FIG. 4 is a perspective view of the shunt resistor according to a second embodiment of the present invention, including the Ia-Ib cross section of the resistive elements of FIG. 1.

FIG. 5 is a cross-sectional view of the shunt resistor according to the second embodiment of the present invention, including the cross section of the resistive elements of FIG. 1 taken along line Ia-Ib.

FIGS. 6A, 6B and 6C illustrate an example of a step of connecting a first terminal and a second terminal to end portions of the resistive elements, and the steps before and after this step.

### DESCRIPTION OF EMBODIMENTS

Hereinafter, a shunt resistor in accordance with embodiments of the present invention will be described in detail with reference to the drawings.

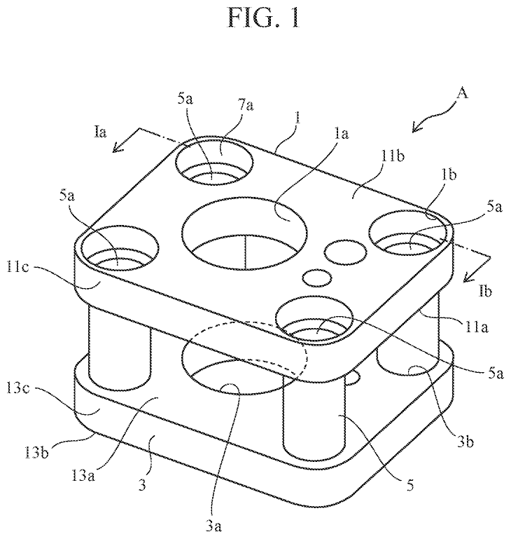

FIG. 1 is a perspective view illustrating an exemplary configuration of a shunt resistor according to an embodiment of the present invention.

A shunt resistor A according to the present embodiment includes: a first terminal (electrode) 1 made of an electrically conductive metal material, such as Cu, and having a first plane 11a, a second plane 11b on the back surface side thereof, and an outer peripheral surface (side surface) 11c around the planes; and a second terminal (electrode) 3 made of an electrically conductive metal material, such as Cu, and having a first plane 13a, a second plane 13b, and an outer peripheral surface (side surface) 13c around the planes.

Further, the first terminal 1 and the second terminal 3 respectively have hole portions 1a, 3a penetrating through from the first planes 11a, 13a to the second planes 11b, 13b.

The respective first planes 11a, 13a of the first terminal 1 and the second terminal 3 oppose each other, and a plurality of resistive elements 5 that connect the first terminal 1 and the second terminal 3 are provided in parallel on the respective first planes 11a, 13a. As the material of the resistive elements 5, Cu—Ni based, Cu—Mn based, and Ni—Cr based metal materials, for example, manganin, can be used.

The area of the end portions 5a, 5b of the resistive elements 5 with respect to the first plane 11a and 13a is smaller than the area of the first planes 11a, 13a. In the present example, the plurality of resistive elements 5 are arranged concentrically about the hole portions (center holes) 1a, 3a respectively formed in the first terminal 1 and the second terminal 3 at four corners. The number of resistive elements 5 and the arrangement thereof are not limited thereto, and may, be changed appropriately.

It should be noted that the first terminal 1 and the second terminal 3 may be polygonal, such as triangular, as well as rectangular, and may be circular. The hole portions 1a, 3a may be polygonal, such as rectangular, as well as circular.

### First Embodiment

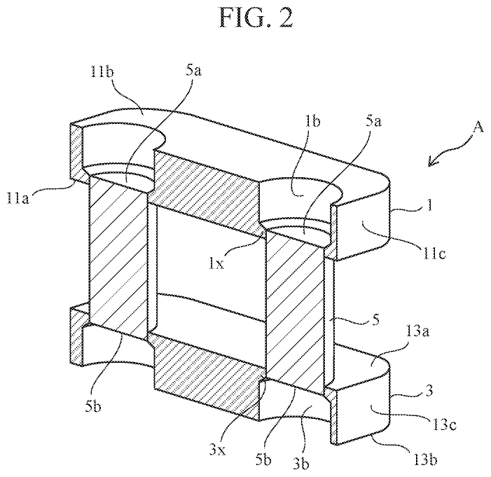

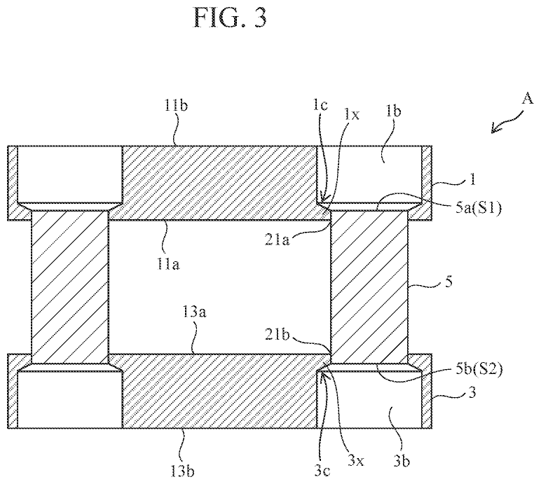

FIG. 2 is a perspective view of a shunt resistor according to a first embodiment of the present invention, including the Ia-Ib cross section of the resistive elements of FIG. 1. FIG. 3 is a cross-sectional view of the shunt resistor according to the first embodiment of the present invention, including the cross section of the resistive elements of FIG. 1 taken along line Ia-Ib.

As illustrated in FIG. 1 to FIG. 3, the first terminal 1 and the second terminal 3 respectively have through-holes 1b, 3b (hereinafter referred to as “counterbores”) that penetrate through the first terminal 1 and the second terminal 3 in the regions contacting the end portions 5a(S1), 5b(S2) of the resistive element 5. On the respective contact surfaces between the first terminal 1 and second terminal 3 and the resistive element 5, the counterbores 1b, 3b are formed in regions substantially equal to the end portions 5a(S1), 5b(S2) of the resistive element 5 and have a substantially equal area. However, the connection area and the connection aspect are not limited thereto. For example, in FIG. 2 and FIG. 3, the end portions of the resistive element 5 are partially embedded in the respective through-holes 1b, 3b of the first terminal 1 and the second terminal 3 in a depth direction thereof.

The counterbores 1b, 3b may each have a diameter that is reduced in the depth direction at positions (in the depth direction) connected to the end portions 5a, 5b of the resistive element 5 on the sides of the first planes 11a, 13a of the first terminal 1 and the second terminal 3. This configuration can form flange portions 1x, 3x on the sides of the first planes 11a, 13a of the first terminal 1 and the second terminal 3. In this case as well, on the respective contact surfaces between the terminals and the resistive element, the flange portions 1x, 3x may, preferably be formed in the regions substantially equal to the end portions of the resistive element 5, that is, in regions that narrow by the area corresponding to the counterbores.

Regions connecting the end portions 5a, 5b of the resistive element 5 to opening edge portions 1c, 3c of the counterbores 1b, 3b of the first terminal 1 and the second terminal 3 respectively have ring-shaped alloy portions 21a, 21b formed along the outer peripheries of the first terminal 1 and the second terminal 3 by alloying an electrode (terminal) material and a resistive material through laser beam welding or electron beam (EB) welding, for example.

As described above, according to the present embodiment, the laser welding allows ensuring structural strength of the shunt resistor A. In addition, soldering allows ensuring electrical characteristics. Through such composite structure formation, a shunt resistor with stable performance can be manufactured.

According to the present embodiment, it is possible to reduce the electrical resistance, and also suppress partial imbalance of the current density and the heat transfer effect and reduce manufacturing variations of a resistance value by leveling the current density. In addition, the heat transfer effect (ensuring a heat transfer area) produces the effect of suppressing local heating at a large current.

### Second Embodiment

Next, a second embodiment of the present invention will be described.

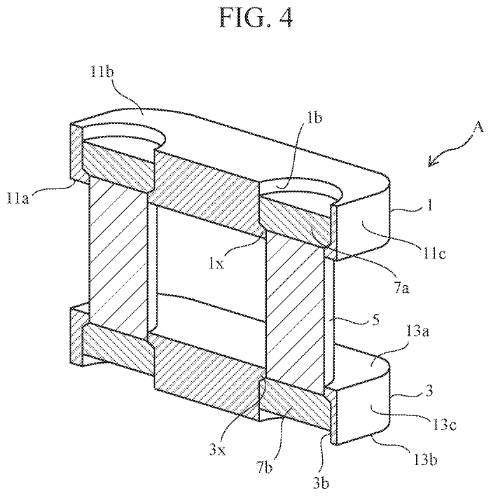

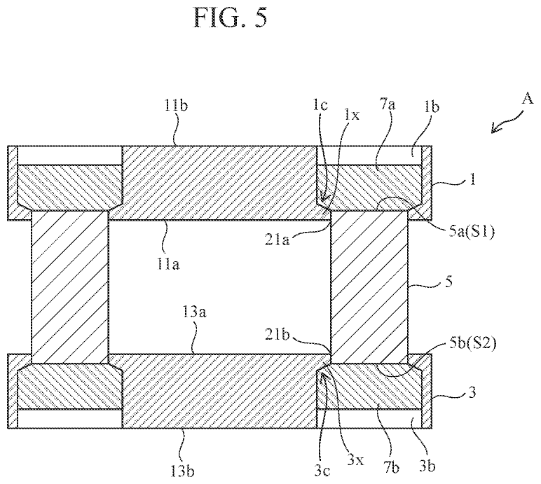

FIG. 4 is a perspective view of the shunt resistor according to the second embodiment of the present invention, including the Ia-Ib cross section of the resistive elements of FIG. 1. FIG. 5 is a cross-sectional view of the shunt resistor according to the second embodiment of the present invention, including the cross section of the resistive elements of FIG. 1 taken along line Ia-Ib. In the shunt resistor illustrated in FIG. 4 and FIG. 5, as compared to FIG. 2, the counterbores 1b, 3b of the first terminal 1 and the second terminal 3 are each filled with solder material, and thus have solder material filled portions 7a, 7b respectively formed therein.

According to the present embodiment, the flange portions 1x, 3x allow the solder material filled portions 7a, 7b connected to the resistive element 5 to be securely fixed in the first terminal 1 and the second terminal 3.

The counterbores 1b, 3b of the first terminal 1 and the second terminal 3 are each filled with solder material, and thus have the solder material filled portions 7a, 7b respectively formed therein. The flange portions 1x, 3x allow the solder material filled portions 7a, 7b connected to the resistive element 5 to be securely fixed in the first terminal 1 and the second terminal 3.

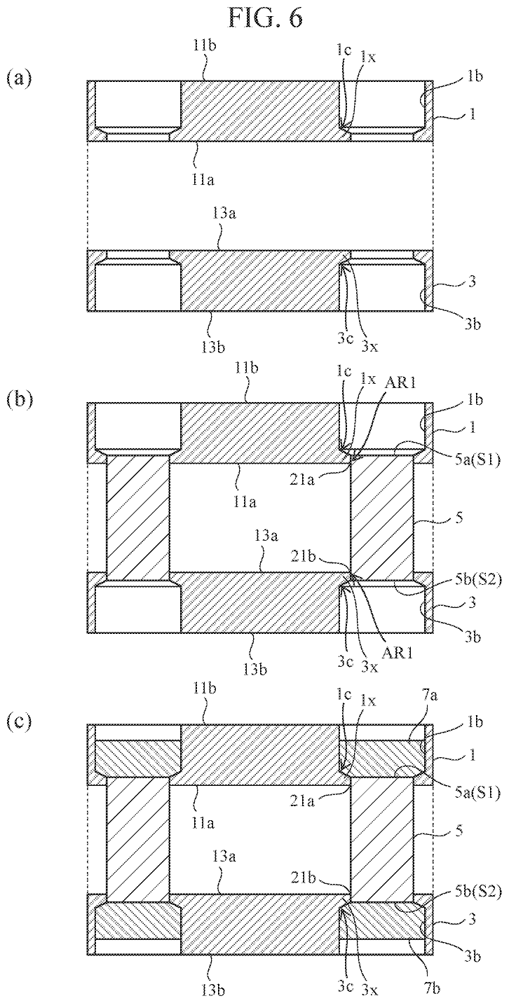

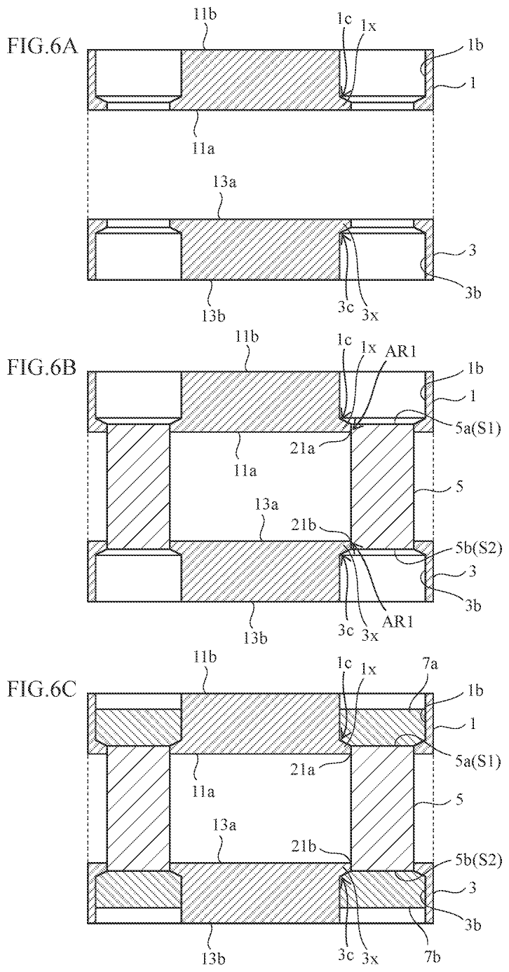

FIGS. 6A to 6C illustrate an example of a step of connecting the first terminal 1 and the second terminal 3 to the end portions 5a, 5b of the resistive element 5, and the steps before and after this step.

As illustrated in FIG. 6A, the counterbores 1b, 3b are formed in the first terminal 1 and the second terminal 3. At this time, the counterbores 1b, 3b are machined to form the flange portions 1x, 3x.

As illustrated in FIG. 6B, the first terminal 1 and the second terminal 3 are arranged opposite each other so as to align the positions of the counterbores 1b, 3b. Next, the first terminal 1, the second terminal 3, and the resistive element 5 are arranged so as to align the regions of the counterbores 1b, 3b with the regions of the end portions 5a, 5b of the resistive element 5.

Next, laser irradiation AR1 is performed on the boundary between the end portions 5a, 5b of the resistive element 5 and the opening edge portions 1c, 3c of the counterbores 1b, 3b of the first terminal 1 and the second terminal 3. More specifically, the end portions 5a, 5b of the resistive element 5 are joined to the opening edge portions 1c, 3c of the counterbores 1b, 3b of the first terminal 1 and the second terminal 3 by performing laser welding in a circular manner along the opening edge portions 1c, 3c. Then, the laser-welded parts become the alloy portions 21a, 21b including an alloy, thereby connecting the first terminal 1 and the second terminal 3 to the resistive element 5. The laser welding allows ensuring structural strength. It should be noted that the outer peripheral part is ring-shaped due to a trace of laser.

As illustrated in FIG. 6C, in a state where the end portions 5a, 5b of the resistive element 5, the first terminal 1, and the second terminal 3 are fixed by laser welding, solder material is filled into the counterbores 1b, 3b from the sides of open surfaces 11b, 13b thereof, then heated and cooled, thereby forming the solder material filled portions 7a, 7b in the counterbores 1b, 3b.

With the solder material filled portions 7a, 7b connected to the end portions 5a, 5b of the resistive element 5, the electrical resistance between the resistive element 5 and the terminals 1, 3 can be reduced.

As described above, the laser welding allows ensuring structural strength of the shunt resistor A. In addition, soldering allows ensuring electrical characteristics. Through such composite structure formation, a shunt resistor with stable performance can be manufactured.

It should be noted that in the manufacturing steps of FIGS. 6A to 6C, the solder material filling step of FIG. 6C may be omitted in the first embodiment.

It should be noted that FIG. 4 through FIGS. 6A to 6C illustrate an example in which about 70% of the volume of the counterbores 1b, 3b is filled with the solder material filled portions 7a, 7b. However, the filling rate of the solder materials 7a, 7b inside the counterbores 1b, 3b is not limited thereto, and 100% of the volume of the counterbores 1b, 3b may be filled with the solder materials 7a, 7b. Such an aspect is also included in the present invention. Both aspects can improve the balance of the current density.

In the foregoing embodiments, the configurations and the like illustrated in the drawings are not limiting, and may be modified, as appropriate, as long as the effects of the present invention can be obtained. Other modifications may be made and implemented, as appropriate, without departing from the scope of the purpose of the present invention. The constituent elements of the present invention may be selectively employed or not employed, and an invention provided with a selected configuration is also included in the present invention.

### INDUSTRIAL APPLICABILITY

The present invention is applicable to shunt resistors.

1. A shunt resistor comprising:
a first terminal and a second terminal each made of an electrically conductive metal material; and
a resistive element disposed between the first terminal and the second terminal,
wherein:
the first terminal and the second terminal each have a through-hole;
the resistive element is embedded in the through-holes of the first terminal and the second terminal in a depth direction thereof; and
regions connecting the resistive element to the first terminal and the second terminal each have an alloy portion formed along an inner peripheral surface of the through-hole.

2. The shunt resistor according to claim 1, wherein:
the resistive element includes a plurality of resistive elements; and
the plurality of resistive elements are provided in parallel and connect the first terminal and the second terminal together.

3. The shunt resistor according to claim 1, wherein the first terminal and the second terminal each have a flange portion formed at a position connected to the resistive element by reducing a diameter of the through-hole toward the position connected to the resistive element.

4. The shunt resistor according to claim 1, wherein:
at least a portion of the through-hole is filled with solder; and
the resistive element is connected to a surface of the solder.

5. The shunt resistor according to claim 2, wherein the first terminal and the second terminal each have a flange portion formed at a position connected to the resistive element by reducing a diameter of the through-hole toward the position connected to the resistive element.

6. The shunt resistor according to claim 2, wherein:
at least a portion of the through-hole is filled with solder; and
the resistive element is connected to a surface of the solder.
